(19) United States
(12) Patent Application Publication
(10) Pub. No.: US 2009/0091887 A1
(43) Pub. Date: Apr. 9, 2009

(54) Cooling system for embedded television

(76) Inventor: Hsien-Yi Huang, Hsichih (TW)

Correspondence Address: BRUCE H. TROXELL, SUITE 1404, 5205 LEESBURG PIKE, FALLS CHURCH, VA, 22041, US

(21) Appl. No.: 12/078,661

(22) Filed: Apr. 2, 2008

(30) Foreign Application Priority Data
Oct. 8, 2007 (TW) 096129612

(51) Int. Cl. H05K 7/20

(52) U.S. Cl. 361/694

(57) ABSTRACT

A cooling system for an embedded television is a structure disposed with a dissipating space for receiving a television; first and second air paths are circulated by air with the dissipating space; the first air path is used for guiding cold air to enter an inside of the dissipating space, the second air path is used for expelling hot air out of the inside of the dissipating space, and a general indoor air condition/exhaust system is utilized to cool the embedded television to allow the effective cooling to be proceeded on the embedded television so as to elongate the use of the television.

### BACKGROUND OF THE INVENTION

1. Field of the Invention

The present invention relates to a cooling system, and more particularly to a cooling system for an embedded television.

2. Description of Related Art

As thin television products are popularized, the placement of the television is different from an old CRT television that can only be placed on a television stand; the thin television tends to be hung on a wall or embedded in the wall, for example, Taiwan Patent No. M292761 discloses an artistic receiving bracket for an embedded concealed thin display. A back face of television embedded in a wall is sealed in a dissipating space of the wall; the television will be caused to be in a high temperature environment if there is lack of a good cooling system to cause electronic components to be damaged easily. Therefore, the cooling system of a television is even more important to an embedded television.

### SUMMARY OF THE INVENTION

For allowing an embedded television to have a better cooling effect, the present invention is proposed.

The main object of the present invention is to provide a cooling system for an embedded television, used for cooling heat generated from the embedded television simply by means of a general indoor air condition/exhaust system.

Another object of the present invention is to provide a cooling system for an embedded television, allowing an effective cooling to be proceeded on the embedded television so as to elongate the use of the television by means of the disposition of a cooling system.

For attaining to the objects mentioned above, the present invention proposes a cooling system for an embedded television comprising:
a structure, for accommodating a television having dissipating space around the television;
a shield plate, connected to the structure and used for sealing a gap between the television and the dissipating space;
a first air path, circulated with a space by air inside the dissipating space; and
a second air path, circulated with the space by air inside the dissipating space;
wherein the first air path is used for guiding cold air to enter a space of around TV (an inside of the dissipating space), the second air path is used for expelling hot air out of the inside of the dissipating space, and a general indoor air condition/exhaust system is used for cooling the embedded television to enable the embedded television to be proceeded with the effective cooling so as to elongate the use of the television.

The present invention also proposes another cooling system for an embedded television comprising:
a structure, disposed with a dissipating space for receiving a television; and
a first air path, circulated by air with a space inside the dissipating space;
wherein the first air path is used for guiding cold air to enter an inside of the dissipating space, and a general indoor air condition/exhaust system is used for cooling the embedded television to enable the embedded television to be proceeded with the effective cooling so as to elongate the use of the television.

### BRIEF DESCRIPTION OF THE DRAWINGS

The present invention can be more fully understood by reference to the following description and accompanying drawings, in which:

FIG. 1 is a schematic front view of a cooling system of a first preferred embodiment according to the present invention;

FIG. 2 is a schematic view of the cooling system of the first embodiment according to the present invention;

FIG. 3 is a schematic front view of a cooling system of a second preferred embodiment according to the present invention;

FIG. 4 is a schematic view of the cooling system of the second embodiment according to the present invention;

FIG. 5 is a schematic front view of a cooling system of a third preferred embodiment according to the present invention;

FIG. 6 is a schematic view of the cooling system of the third embodiment according to the present invention;

FIG. 7 is a schematic front view of a cooling system of a fourth preferred embodiment according to the present invention; and

FIG. 8 is a schematic view of the cooling system of the fourth embodiment according to the present invention.

### DETAILED DESCRIPTION OF THE PREFERRED EMBODIMENTS

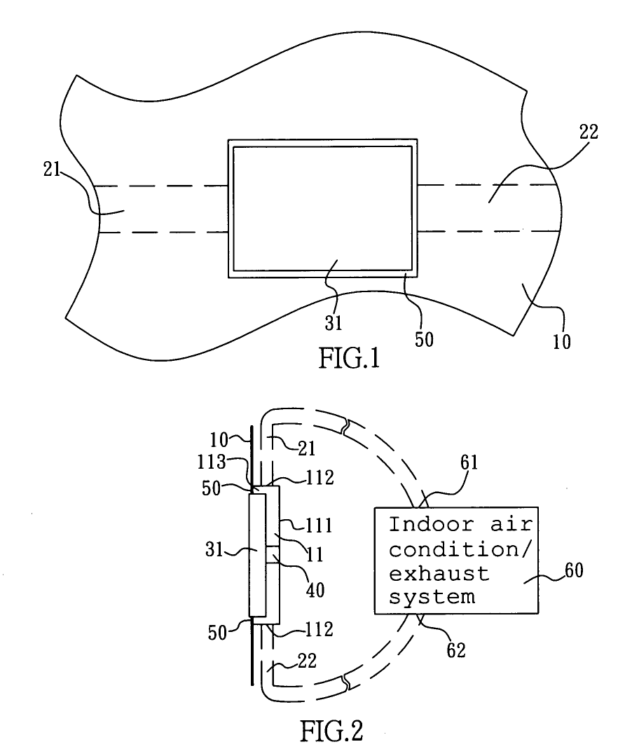

Please refer to FIGS. 1 and 2. FIGS. 1 and 2 are schematic views showing a cooling system for an embedded television of a first preferred embodiment according to the present invention. The cooling system mainly comprises a structure 10, a first air path 21 and a second air path 22. A groove 11 for receiving a television 31 is disposed on the structure 10 as a dissipating space as FIG. 2 shows, in which the groove 11 is provided with an inner wall 111 and a side wall 112 surrounding the inner wall 111. The structure 10 is for accommodating the television 31, and having dissipating space around the television.

A fixing element 40 is coupled to the inner wall 111 or the side wall 112 of the groove 11; the fixing element 40 is coupled to the inner wall 111 in the embodiment. In the meantime, the fixing element 40 is coupled to the television 31 to cause a back part of the television 31 to be fixed in the groove 11. A shielding plate 50 is respectively connected to the structure 10 and the television 31 to seal a gap 113 between the television 31 and the groove 11.

The first and the second air paths 21, 22 are respectively circulated with a space by air inside the groove 11 and communication parts are hid in the structure 10. The first and the second air paths 21, 22 are respectively circulated by air with an air outlet 61 and an air inlet 62 of an indoor air condition/exhaust system 60. The structure 10 may be a wall, decoration panel or cabinet.

The present embodiment is a cooling way that air flows in and out respectively through left and right ends of the groove 11; connections of the first and the second air paths 21, 22 are respectively at the left and the right ends of the groove 11; cold air may flow into the groove 11 through the left end thereof and hot air may flow out of the groove 11 through the right end thereof. But, cold air is also allowed to flow into the groove 11 through the right end thereof and hot air is allowed to flow out of the groove 11 through the left end thereof in another aspect. Such kind of cooling way is rather suitable for the television 31 with input/output interfaces (I/O) disposed at upper/lower end thereof.

The present embodiment mainly utilizes the indoor air condition/exhaust system 60 to proceed cooling for the television 31. Cold air expelled out of the indoor air condition/exhaust system 60 through the air outlet 61 is guided into the groove 11 through the first air path 21 to proceed cooling to the television 31 and then, hot air is guided into the indoor air condition/exhaust system 60 through the air inlet 62 of the indoor air condition/exhaust system 60. Besides, the second air path 22 may be circulated by air with the outdoors and not circulated by air with the air inlet 62 of the indoor air condition/exhaust system 60 to allow hot air to be expelled to the outdoors directly.

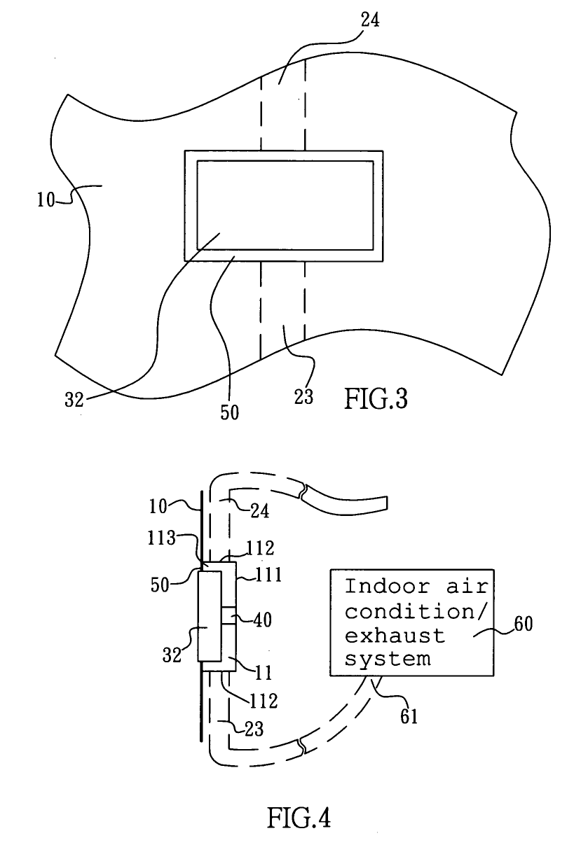

Please refer to FIGS. 3 and 4. FIGS. 3 and 4 are schematic views showing a cooling system for an embedded television of a second preferred embodiment according to the present invention. The second embodiment is almost similar to the cooling system of the first embodiment shown in FIGS. 1 and 2 except that connections of first and second air paths 23, 24 and the groove 11 are respectively positioned at lower and upper ends of the groove 11, and the second air path 24 is circulated by air with the outdoors together with the first air path 23 is circulated by air with the air outlet 61 of the indoor air condition/exhaust system 60; the second air path 24 may also be circulated by air with the air inlet 62 of the indoor air condition/exhaust system 60. The present embodiment is a cooling way that air flows in and out respectively through lower and upper ends of the groove 11; under consideration of physical characteristic of natural convention, it is a more ideal cooling way by allowing cold air to flow into the groove 11 from the lower end thereof and hot air to flow out of the groove 11 through the upper end thereof. Such kind of cooling way is more suitable for a television 32 with input/output interfaces disposed at right and left ends thereof.

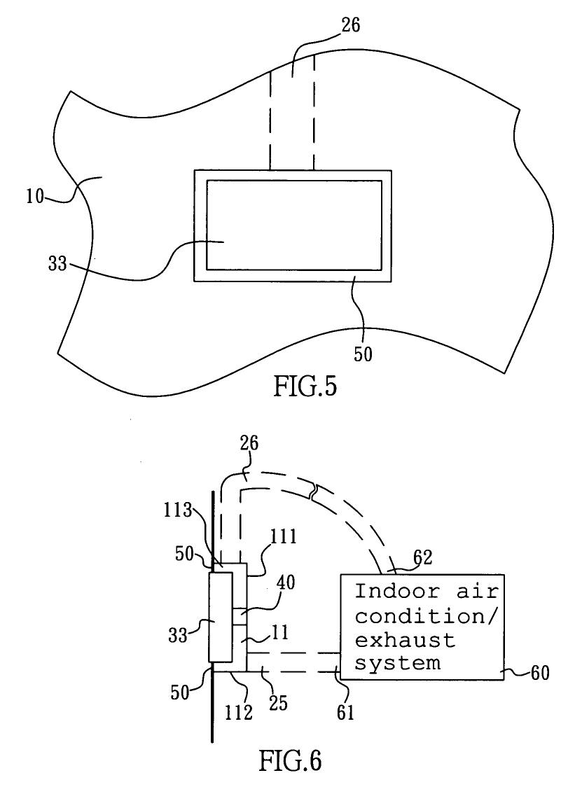

Please refer to FIGS. 5 and 6. FIGS. 5 and 6 are schematic views showing a cooling system for an embedded television of a third preferred embodiment according to the present invention. The third embodiment is almost similar to the cooling system of the first embodiment shown in FIGS. 1 and 2 except that connections of first and second air paths 25, 26 and the groove 11 are respectively circulated by air with a lower end of the inner wall 111 and the upper end of the groove 11, the first air path 25 is circulated by air with the air outlet 61 of the indoor air condition/exhaust system 60 and the second air path 26 is circulated by air with the air inlet 62 of the indoor air condition/exhaust system 60. The present embodiment is a cooling that air flows into the lower end of the inner wall and out of the upper end of the groove 11; it considers not to disobey a natural convection direction similar to the second embodiment: cold air enters the groove 11 through the lower end of the inner wall 111 and hot air is exhausted through the upper end of the groove 11; this also is a better cooling disposition. This kind of cooling way is rather suitable for a television 33 with input/output interfaces disposed on left, right and lower sides thereof.

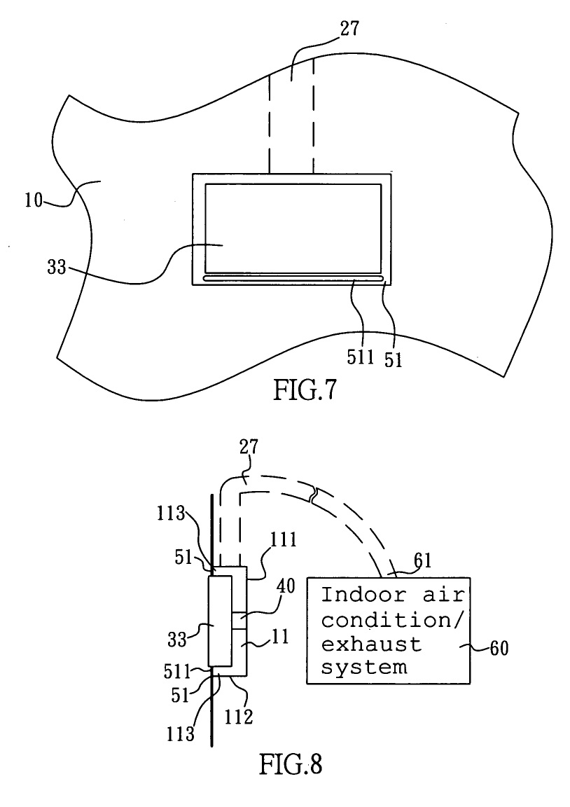

Please refer to FIGS. 7 and 8. FIGS. 7 and 8 are schematic views showing a cooling system for an embedded television of a fourth preferred embodiment according to the present invention. The fourth embodiment is almost similar to the cooling system of the third embodiment shown in FIGS. 5 and 6 except that a connection of a first air path 27 and the groove 11 is positioned at the upper end of the groove 11 and the first air path 27 is circulated by air with the air outlet 61 of the indoor air condition/exhaust system 60, but there is no second air path needed to dispose. Furthermore, a ventilation hole is disposed on a lower end of the shielding plate 51. The present embodiment is a cooling way that cold air flows into the groove 11 via the upper end thereof; the cold air is spread from the upper end of the groove 11 toward a lower side thereof to cool the television 33 and then, hot air is expelled out of the groove 11 via the ventilation hole 511 of the shielding plate 51; this is a better cooling disposition. Such kind of cooling way is more suitable for a television 33 with input/output interfaces disposed on the left, the right and the lower sides thereof. The present embodiment also allows the shielding plate 51 not to shield the gap 113 between a lower end of the television 33 and the groove 11 to enable hot air to be expelled out of the groove 11 via the gap 113 between the lower end of the television 33 and the groove 11.

The cooling system for an embedded television of the present invention is used for the cooling of the embedded television by utilizing a general indoor air condition/exhaust system, and effective cooling is processed on the embedded television by matching the simple first and second air paths or using the disposition of only the first air path to elongate the use of the television.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A cooling system for an embedded television, comprising:
a structure, for accommodating a television having dissipating space around the television;
a first air path, circulated with said space by air around said television; and
a second air path, circulated with said space by air around said television;
wherein said first air path is for guiding cold air to enter the space around television, said second air path is for quiding hot air out of said space thereby cooling said television.

2. The cooling system according to claim 1, further comprising a shielding plate, usded for covering a gap between said structure and said television.

3. The cooling system according to claim 1, wherein said first and said second air paths are respectively circulated by air with an air outlet and an air inlet of a air condition system.

4. The cooling system according to claim 3, wherein said air condition system is an indoor air condition system.

5. The cooling system according to claim 1, wherein said first air path is circulated by air with an air outlet of an air exhaust system.

6. The cooling system according to claim 5, wherein said air exhaust system is an indoor air exhaust system.

7. The cooling system according to claim 6, wherein said second air path is circulated by air with the outdoors.

8. The cooling system according to claim 1, wherein said dissipating space is provided with an inner wall and a side wall surrounding said inner wall, at least one of said inner wall and said side wall of said dissipating space is coupled to a fixing element, said fixing element is used for coupling to said television thereby allowing a back part of said television to be fixed in said dissipating space.

9. The cooling system according to claim 8, wherein connections of said first, said second air paths and said dissipating space are respectively positioned at one of left and right ends of said dissipating space.

10. The cooling system according to claim 8, wherein connections of said first, said second air paths and said dissipating space are respectively positioned at lower, upper ends of said dissipating space.

11. The cooling system according to claim 8, wherein connections of said first and said second air paths and said dissipating space are respectively positioned at a lower end of said inner wall and said lower end of said dissipating space.

12. The cooling system according to claim 9, wherein said structure is selected from the group consisting of a wall and a decoration panel.

13. A cooling system for an embedded television, comprising:
a structure, disposed with a dissipating space for receiving a television; and
a first air path, circulated by air with a space inside said dissipating space;
wherein said air path is used for guiding cold air to enter an inside of said space thereby allowing said television to be cooled.

14. The cooling system according to claim 13, further comprising a shielding plate connected to said structure and used for sealing a gap between a part beside a lower end of said television and said dissipating space to allow a gap to exist between a lower end part of said television and said dissipating space to be used for expelling air; a connection of said first air path and said dissipating space is positioned at a upper end of said dissipating space.

15. The cooling system according to claim 13, further comprising a shielding plate connected to said structure and used for sealing a gap between said television and said dissipating space; said shielding plate being disposed with a ventilation hole used for expelling air.

16. The cooling system according to claim 15, wherein a connection of said first air path and said dissipating space is positioned at a upper end of said dissipating space; said ventilation hole is disposed on a lower end of said shielding plate.

17. The cooling system according to claim 13, wherein said dissipating space is provided with an inner wall and a side wall surrounding said inner wall, at least one of said inner wall and said side wall of said dissipating space is coupled to a fixing element, said fixing element is used for coupling to said television thereby allowing a back part of said television to be fixed in said dissipating space.

18. The cooling system according to claim 17, wherein said first air path is circulated by air with an air outlet of an air condition system.

19. The cooling system according to claim 18, wherein said air condition system is an indoor air condition system.

20. The cooling system according to claim 18, wherein said structure is selected from the group consisting of a wall and a decoration panel.

21. The cooling system according to claim 17, wherein said first air path is circulated by air with an air outlet of an air exhaust system.

22. The cooling system according to claim 21, wherein said air exhaust system is an indoor air exhaust system.

23. The cooling system according to claim 22, wherein said structure is selected from the group consisting of a wall and a decoration panel.
